(19) United States
(12) Patent Application Publication
(10) Pub. No.: US 2008/0230766 A1
(43) Pub. Date: Sep. 25, 2008

(54) Light emitting device

(75) Inventors: Kuniyoshi Okamoto, Kyoto-shi (JP); Hiroaki Ohta, Kyoto-shi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/076,658

(22) Filed: Mar. 20, 2008

(30) Foreign Application Priority Data
Mar. 23, 2007 (JP) 2007-077037

(51) Int. Cl. H01L 33/00; H01L 29/06

(52) U.S. Cl. 257/13; 257/94; 257/E29.168; 257/E33.023; 257/E33.068

(57) ABSTRACT

A light emitting element includes a group III nitride semiconductor substrate that emits a light by absorbing a UV ray and a light emitting diode structure. The light emitting diode structure is formed of a group III nitride semiconductor grown on the group III nitride semiconductor substrate, and has a p-type layer, an active layer that emits a light having a wavelength in the UV region, and an n-type layer. It is preferable that the group III nitride semiconductor substrate has a principal plane of a non-polar plane or a semi-polar plane and the group III nitride semiconductor having a same plane orientation as that of the principal plane is grown on the principal plane.

### BACKGROUND OF THE INVENTION

1. Field of the Invention

The present invention relates to a light emitting element having a light emitting diode structure using a nitride semiconductor.

2. Description of Related Art

Of the group III-V semiconductors, semiconductors using nitrogen as group V elements are referred to as group III nitride semiconductors. Representative examples are aluminum nitride (AlN), gallium nitride (GaN), and indium nitride (InN). Generally, they are expressed as AlₓIn_{y}Ga_{1-x-y}N, where 0≦x≦1, 0≦y≦1, and 0≦x+y≦1.

A manufacturing method of a nitride semiconductor has been known to grow group III nitride semiconductor on a gallium nitride (GaN) substrate having the principal plane in c-plane by metal organic chemical vapor deposition (MOCVD). By adopting this method, it is possible to form a GaN semiconductor laminating structure having an n-type layer and a p-type layer to fabricate a light emitting device using this laminating structure. Such a light emitting device can be used, for example, as a light source of the back light for a liquid crystal panel.

When an active layer having an emission wavelength in a long wavelength band of 500 nm or longer is formed in a group III nitride semiconductor, such an active layer is known for vulnerability to heat damage. To be more concrete, for instance, a case will be described as an example where a light emitting diode structure is formed by growing an n-type GaN semiconductor layer on a GaN substrate to laminate an active layer made of a group III nitride semiconductor thereon and by further growing a p-type GaN semiconductor layer on the active layer. In this case, in order to achieve an emission wavelength of 500 nm or longer, it is necessary that indium is taken into the active layer. To this end, the substrate temperature while the active layer is grown is set at 700° C. to 800° C. Meanwhile, the substrate temperature is set at 800° C. or higher while the p-type GaN layer is epitaxially grown so as to be formed on the active layer. The active layer undergoes heat damage in this instance, and emission efficiency is impaired significantly. It is therefore by no means easy to achieve an emission wavelength of 500 nm or longer.

In a case where a yellow or white light emitting diode is fabricated using group III nitride semiconductors, a fluorescent material is often applied on the surface of the light emitting diode chip having an active layer having an emission wavelength no longer than 500 nm. The applying work, however, is tedious.

As described above, it is by no means easy to obtain a light emission in a long wavelength band (for example, 500 nm or longer; a wavelength band from green to yellow) using a group III nitride semiconductor.

### SUMMARY OF THE INVENTION

An object of the invention is to provide a light emitting element of a structure capable of obtaining a light emission in a long wavelength band easily without deteriorating emission efficiency in the active layer.

A light emitting element of the invention includes a group III nitride semiconductor substrate that emits a light (preferably, it emits yellow light and other visible light) by absorbing a UV ray (having a wavelength of 400 nm or shorter), and a light emitting diode structure made of a group III nitride semiconductor grown on the group III nitride semiconductor substrate and having a p-type layer, an active layer that emits a light having a wavelength in a UV region, and an n-type layer.

According to this configuration, a current is injected in the active layer in the light emitting diode structure so that light in the UV region (short wavelength band) can be emitted. The light in the UV region from the active layer in the light emitting diode structure then is incident on the group III nitride semiconductor substrate to excite the group III nitride semiconductor substrate, whereby a light emission is generated from the group III nitride semiconductor substrate. In this manner, it is possible to generate a short wavelength light in the UV region from the active layer and to generate a light having a different wavelength from the group III nitride semiconductor substrate. Hence, it is possible to achieve a light emission having a long wavelength (for example, yellow light emission) with ease without deteriorating emission efficiency in the active layer.

It is preferable that the group III nitride semiconductor substrate has a principal plane of a non-polar plane or a semi-polar plane, and it is preferable that the group III nitride semiconductor having a same plane orientation as that of the principal plane is grown on the principal plane.

By using a group III nitride semiconductor that has a principal plane of a non-polar plane or a semi-polar plane for crystal growth, which is a different material from the c-plane group III nitride semiconductor, it is possible to suppress separation of carriers due to spontaneous piezoelectric polarization in the active layer and to increase emission efficiency. The non-polar plane is m-plane or a-plane, and examples of the semi-polar plane include (10-1-1) plane, (10-1-3) plane, and (11-22) plane.

In particular, when m-plane is the principal plane for crystal growth, crystals can be grown in an extremely stable manner, and the crystalline property can be enhanced in comparison with a case where c-plane or any another crystal plane is the principal plane for crystal growth. It is thus possible to fabricate a high-performance light emitting diode.

It is preferable that the group III nitride semiconductor is grown by crystal growth on a gallium nitride single crystalline substrate having m-plane as a growth plane for crystal growth. By using a gallium nitride single crystalline substrate having an extremely small dislocation density (preferably having no dislocation density), the group III nitride semiconductor laminating structure forming the light emitting diode structure can be high-quality crystals causing less stacking fault (plane defect) and dislocation (line defect). It is thus possible to fabricate a high-performance light emitting diode. In particular, the group III nitride semiconductor laminating structure can be crystals free of stacking fault or threading dislocation caused from the growth plane of the group III nitride semiconductor substrate. It is thus possible to suppress a factor that can deteriorate the characteristic, such as deterioration in emission efficiency caused by stacking fault or dislocation.

It is preferable that the principal plane of the gallium nitride single crystalline substrate is a plane having an off angle within ±1° from the plane orientation of m-plane. When configured in this manner, it is possible to grow dislocation-free and flat gallium nitride semiconductor crystals in a more reliable manner.

The group III nitride semiconductor substrate may generate a light having a peak wavelength of 500 nm to 600 nm by absorbing UV ray. In addition, the active layer may have a multiple-quantum well structure including a first quantum well layer that generates a light having a wavelength in the UV region and a second quantum well layer that generates a visible light having a wavelength less than 500 nm.

According to this configuration, the light in the UV region generated from the first quantum well layer is incident on the group III nitride semiconductor substrate and a yellow light having a peak wavelength of 500 nm to 600 nm is generated. Meanwhile, a visible light having a wavelength less than 500 nm is generated from the second quantum well layer. Accordingly, it is possible to achieve light emission of mixed colors of a yellow light and a visible light (for example, blue light) with a wavelength less than 500 nm. Hence, white light emission is realized, for example, by mixing the yellow light and the blue light. It is thus possible to achieve a light emitting element that emits white light without deteriorating emission efficiency and without requiring a tedious work, such as application of a fluorescent material.

Light generated from the group III nitride semiconductor substrate and the light generated from the second quantum well layer may have different polarization degrees. According to this configuration, because the polarization degree varies with each wavelength, for example, it is possible to achieve a light emitting device that looks white without a polarization filter (for example, polarization spectacles) while looks yellow when observed through the polarization filter. In addition, by introducing light generated from the light emitting element to pass through a medium whose polarization state is controllable, it is possible to configure a sensing light source. The sensing light source is a light source for the purpose of checking the presence of a response to polarization of a subject material.

For example, when the active layer is made of a group III nitride semiconductor having a principal plane for growth of a non-polar plane, the quantum well layer can emit a polarized light. On the contrary, because light emission from the group III nitride semiconductor substrate that emits light by absorbing the UV ray is light emission from a point defect portion, the light is a random polarized light. It is thus possible to achieve light emission having a different polarization degree that varies with a wavelength.

Further, the light generated from the group III nitride semiconductor substrate may not be polarized and the light generated from the second quantum well layer may be polarized. According to this configuration, it is possible to obtain a light emitting element that emits a light in a state where a light less than 500 nm is polarized and a light of 500 nm or longer is not polarized. Applications same as above are also applicable even when such light emitting element is used.

The light emitting element may be configured such that the light may be extracted from a side of the group III nitride semiconductor substrate. According to this configuration, the light generated from the substrate can be extracted efficiently.

It is preferable that the light extract surface of the light emitting element is a mirror surface. The mirror surface is a surface having a small unevenness in comparison with the emission wavelength (in particular, the wavelength of polarized light), and it means a surface that gives substantially no influences on the polarization state. Hence, by forming the light extract surface as the mirror surface, it is possible to suppress or prevent disturbance of polarization due to scattering. Hence, the generated light can be extracted to the outside with little disturbance on the polarization state.

Other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic cross section describing the structure of a nitride semiconductor light emitting element according to one embodiment of the invention;

FIG. 2 is a schematic view showing a unit cell in the crystal structure of a group III nitride semiconductor;

FIG. 3 is a schematic view describing the configuration of a processing apparatus for growing respective layers that form a GaN semiconductor layer; and

FIG. 4 is a schematic view showing an example of a device exploiting that blue polarized light is generated from a multiple-quantum well layer and yellow random polarized light is generated from a GaN substrate.

### DETAILED DESCRIPTION OF THE PREFERRED EMBODIMENTS

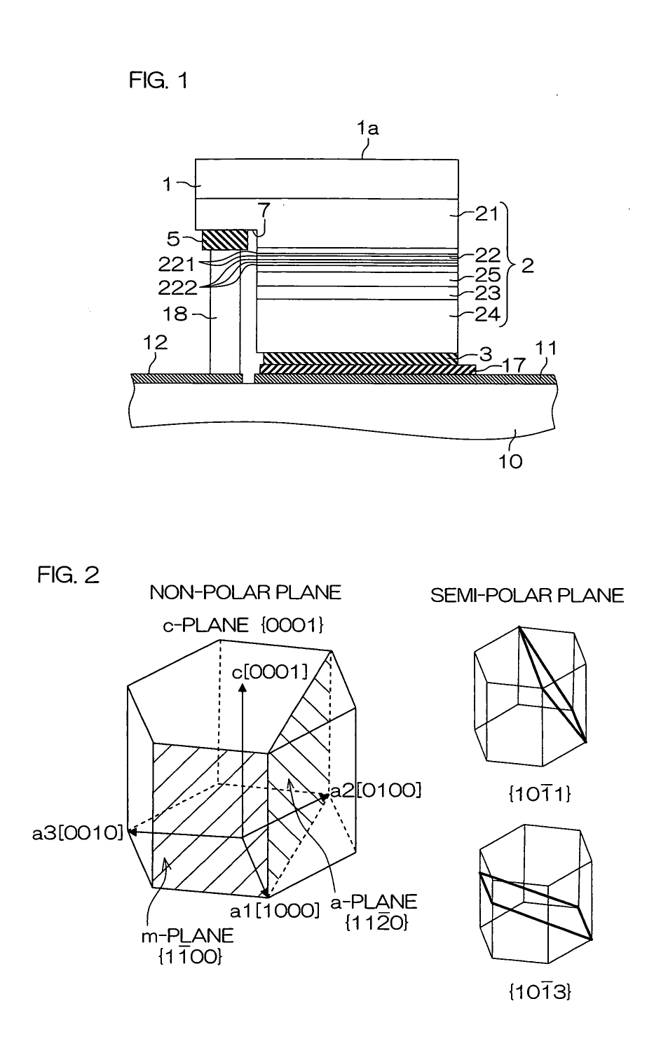

FIG. 1 is a schematic cross section describing the structure of a nitride semiconductor light emitting element according to one embodiment of the invention. The nitride semiconductor light emitting element is formed by growing a group III nitride semiconductor layer 2 as a group III nitride semiconductor laminating structure forming a light emitting diode structure on one principal plane (the bottom surface in FIG. 1) of a GaN (gallium nitride) substrate 1 as an example of a group III nitride semiconductor substrate.

The group III nitride semiconductor layer 2 has a laminating structure formed by sequentially laminating, from the GaN substrate 1 side, an n-type contact layer 21, a multiple-quantum well (MQW) layer 22 as an active layer (emission layer), a GaN final barrier layer 25, a p-type electron block layer 23, and a p-type contact layer 24. An anode electrode (p-type electrode) 3 is formed on the surface of the p-type contact layer 24. Further, a cathode electrode (n-type electrode) 5 is bonded to the n-type contact layer 21. The p-type electron block layer 23 and the p-type contact layer 24 form a p-type layer and the n-type contact layer 21 forms an n-type layer. The multiple-quantum well layer 22 is disposed so as to be sandwiched between these layers.

The anode electrode 3 is bonded (die-bonded) to a wire layer 11 on a supporting substrate 10 via a bonding metal layer (for example, a silver layer) 17. The group III nitride semiconductor layer 2 is etched (for example, by plasma etching) until the n-type contact layer 21 is exposed from the supporting substrate 10 side and a recessed portion 7 is thus formed. The cathode electrode 5 in contact with the n-type contact layer 21 is formed in the recessed portion 7. The cathode electrode 5 and a wire 12 on the supporting substrate 10 are connected by a metal post (for example, a silver post) 18.

The n-type contact layer 21 is formed of a n-type GaN layer added with silicon as an n-type dopant. The layer thickness thereof is preferably 3 μm or larger. The doping concentration of silicon is, for example, 10¹⁸ cm⁻³. To be more concrete, the n-type contact layer 21 is made of an n-type GaN semiconductor grown by crystal growth on the GaN substrate 1.

The multiple-quantum well layer 22 is formed, for example, by laminating a quantum well layer formed of a silicon-doped InGaN layer (for example, the thickness is 3 nm) and a barrier layer formed of a GaN layer (for example, the thickness is 9 nm) alternately in predetermined cycles (for example, five cycles). In this embodiment, the multiple-quantum well layer 22 has a first quantum well layer 221 and a second quantum well layer 222 having different emission wavelengths. The first quantum well layer 221 generates light in a UV region having a wavelength of 300 nm to 400 nm (for example, 370 nm), whereas the second quantum well layer 222 generates blue light (visible light) having a wavelength of 400 nm to 500 nm (for example, 460 nm). In other words, the InGaN layer forming the first quantum well layer 221 is formed with a larger band gap than that of the InGaN layer forming the second quantum well layer 222. The band gap can be adjusted by adjusting a composition ratio of indium (In). As the composition ratio of indium is increased, the band gap becomes smaller and the emission wavelength becomes longer.

The GaN final barrier layer 25 (for example, having the thickness of 40 nm) is laminated between the multiple-quantum well layer 22 and the p-type electron block layer 23. The multiple-quantum well layer 22 is sandwiched between the n-type contact layer 21 and the p-type contact layer 24. The light emitting diode structure is thus formed.

The p-type electron block layer 23 is formed of an AlGaN layer added with magnesium as a p-type dopant. The layer thickness thereof is, for example, 28 nm. The doping concentration of magnesium is, for example, 3×10¹⁹ cm⁻³.

The p-type contact layer 24 is formed of a GaN layer added with magnesium at a high concentration as a p-type dopant. The layer thickness is, for example, 70 nm. The doping concentration of magnesium is, for example, 10²⁰ cm⁻³.

The anode electrode 3 is formed of a transparent thin metal layer (for example, 200 Å or smaller) made of Ni and Au.

The cathode electrode 5 is a film formed of Ti and an Al layer.

When irradiated with UV rays (having wavelength of 400 nm or shorter), the GaN substrate 1 absorbs the UV rays and emits yellow light having a wavelength of 500 nm to 600 nm (for example, 560 nm). Further, it is capable of obtaining a different emission wavelength by including metals, such Fe, Cu, and rare-earth metals.

Light generated from the GaN substrate 1 is extracted to the outside from a light extract surface 1a, which is the principal plane on the side opposite to the group III nitride semiconductor layer 2. The GaN substrate 1 is a substrate made of GaN having the principal plane in a crystal plane other than c-plane. To be more concrete, it is a substrate having a non-polar or a semi-polar plane as the principal plane. Preferably, it is a GaN single crystalline substrate having the principal plane in a surface having an off angle within ±1° from the plane orientation of a non-polar plane or in a surface having an off angle within ±1° from the plane orientation of a semi-polar plane. The lamination principal plane of each layer in the group III nitride semiconductor layer 2 follows the crystal plane of the principal plane of the GaN substrate 1. In other words, the principal plane of the forming layer in the group III nitride semiconductor layer 2 has a crystal plane same as the crystal plane of the principal plane of the GaN substrate 1.

The light extract surface la of the GaN substrate 1 is a mirror surface. In other words, polishing (mirror finishing), such as chemical and mechanical polishing is applied to the light extract surface 1a. Let n₁ (n₁≈2.5) be the refraction index of GaN and λ be the emission wavelength. Then, the light extract surface 1a can be said as a mirror surface that gives substantially no influences to light when the unevenness on the light taking-out surface 1a are λ/n₁ or smaller.

When a forward voltage is applied between the anode electrode 3 and the cathode electrode 5 from the wires 11 and 12, the multiple-quantum well layer 22 is excited-with current injection and emits light. In this instance, UV light is generated from the first quantum well layer 221 and blue light is generated from the second quantum well layer 222. The light emitting mechanism may be diode emission or PL (photoluminescence) emission.

Meanwhile, when light in the UV region generated from the first quantum well layer 221 is incident on the GaN substrate 1, the GaN substrate 1 undergoes light excitation and emits yellow light. Hence, the yellow light generated from the GaN substrate 1 and the blue light generated from the second quantum well layer 222 are mainly extracted from the light extract surface 1a (the top surface in FIG. 1) of the GaN substrate 1 and are observed in a mixed appearance. Hence, it is possible to generate apparently white light.

FIG. 2 is a schematic view showing a unit cell in the crystal structure of a group III nitride semiconductor. The crystal structure of the group III nitride semiconductor can be approximated by a hexagonal system. The plane (the top face of the hexagonal cylinder) having c-axis along the axial direction of the hexagonal cylinder as the normal line is c-plane (0001). In the group III nitride semiconductors, the polarization direction goes along c-axis. Accordingly, c-plane shows different properties on the +c-axis side and on the -c-axis side, and c-plane is therefore called a polar plane. Each of the side faces of the hexagonal cylinder is m-plane (10-10) and a plane passing a pair of ridge lines that are not adjacent to each other is a-plane (11-20). Because these planes are crystal planes at right angles with respect to c-plane and orthogonal to the polarization direction, they are planes having no polarity, that is, non-polar planes. Further, because crystal planes that incline with respect to c-plane (neither parallel to nor at right angles with c-plane) diagonally crosses the polarization direction, they are planes having slight polarization, that is, semi-polar planes. Concrete examples of the semi-polar planes include (10-1-1) plane, (10-1-3) plane, and (11-22) plane.

T. Takeuchi et al., Jap. J. Appl. Phys. 39, 413-416, 2000 discloses the relation between the angle of deviation of the crystal plane with respect to c-plane and the polarization in the normal direction of the crystal plane. From this reference document, it can be understood that planes, such as (11-24) plane and (10-12) plane, are also crystal planes having less polarization. From an emission layer grown by crystal growth using a crystal plane (non-polar plane or semi-polar plane) having less polarization as the principal plane, light having a high polarization degree is generated. For example, when the multiple-quantum well layer 22 is formed using the principal plane for growth in m-plane, light significantly polarized in a-axis direction is obtained.

For example, a GaN single crystalline substrate having the principal plane in m-plane can be manufactured by cutting out from GaN single crystals having the principal plane in c-plane. The m-plane of the cut-out substrate is polished, for example, by chemical and mechanical polishing until an orientation error with respect to both the (0001) direction and the (11-20) direction falls within ±1° (preferably within ±0.3°). A GaN single crystalline substrate having the principal plane in m-plane and free of dislocation and stacking fault can be thus obtained. Steps merely at the atomic level are present on the surface of such a GaN single crystalline substrate.

The group III nitride semiconductor layer 2 can be grown on the GaN single crystalline substrate thus obtained as above by MOCVD.

The group III nitride semiconductor layer 2 having the principal plane for growth in m-plane is grown on the GaN single crystalline substrate 1 having the principal plane in m-plane and the cross section along a-plane is observed using a scanning transmission electron microscope (STEM). Then, a striation indicating the presence of dislocation is not seen in the group III nitride semiconductor layer 2. Further, an observation of the surface state using an optical microscope reveals that the flatness (a difference in height between the end portion and the bottom portion) in c-axis direction is 10 Å or less. This means that the flatness in c-axis direction of the multiple-quantum well layer 22, in particular, the quantum well layers 221 and 222 is 10 Å or less. Accordingly, the half bandwidth of an emission spectrum can be smaller.

As has been described, it is possible to grow an m-plane group III nitride semiconductor having no dislocation and a flat deposition interface. It should be noted, however, that the off angle of the principal plane of the GaN single crystalline substrate 1 preferably falls within ±1° (more preferably ±0.3°). For example, when a GaN semiconductor layer is grown on an m-plane GaN single crystalline substrate having the off angle of 2°, GaN crystals are grown in the shape of a terrace, and a surface state as flat as that obtained in the case of setting the off angle within ±1° may not be obtained.

The group III nitride semiconductor to be grown by crystal growth on the GaN single crystalline substrate having the principal plane in m-plane is grown to have the principal plane for growth in m-plane. In a case where it is grown by crystal growth having the principal plane in c-plane, emission efficiency in the emission layer 10 may possibly be deteriorated because of influences of polarization in c-axis direction. On the contrary, in a case where it is grown having the principal plane for crystal growth in m-plane, polarization in the quantum well layers is suppressed and emission efficiency can be therefore increased.

In addition, by configuring such that the principal plane for crystal growth lies in m-plane, group III nitride semiconductor crystals can be grown extremely stable. The crystalline property can be therefore enhanced in comparison with a case where the principal plane for crystal growth in c-plane or a-plane. It is thus possible to manufacture a high-performance light emitting diode structure.

Further, in this embodiment, because a GaN single crystalline substrate is used as the substrate 1, the group III nitride semiconductor layer 2 can have a high crystalline quality with less dislocation. It is thus possible to achieve a high-performance light emitting diode.

Further, by growing the group III nitride semiconductor layer 2 on the GaN single crystalline substrate having substantially no dislocation, the group III nitride semiconductor layer 2 can be satisfactory crystals having no stacking fault or threading dislocation from the grown surface (m-plane) of the substrate 1. It is thus possible to suppress characteristic deterioration, such as deterioration in emission efficiency caused by stacking fault (plane defect) and dislocation (line defect).

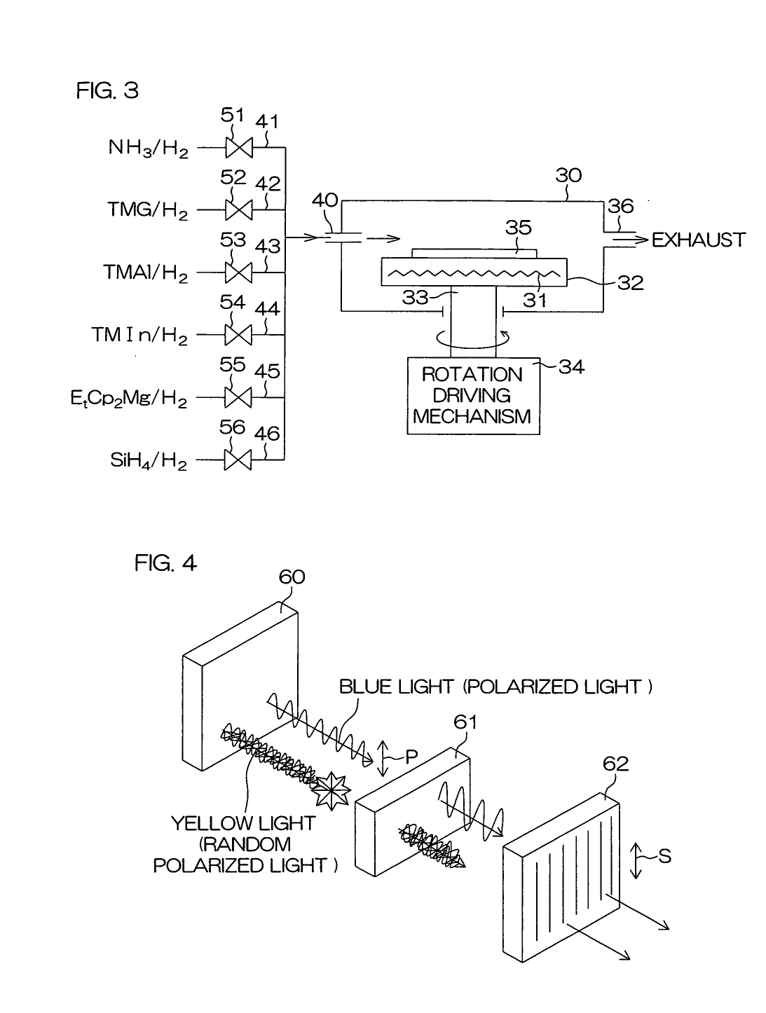

FIG. 3 is a schematic view describing the configuration of a processing apparatus to grow respective layers that form the group III nitride semiconductor layer 2. A susceptor 32 enclosing a heater 31 is installed in a process chamber 30. The susceptor 32 is coupled to a rotating shaft 33, and the rotating shaft 33 is rotated by a rotation driving mechanism 34 arranged in the exterior of the process chamber 30. Accordingly, by holding a wafer 35 to be processed with the susceptor 32, it is possible to heat the wafer 35 to a specific temperature, and to rotate the wafer 35 inside the process chamber 30. The wafer 35 is, for example, a GaN single crystalline wafer that forms the GaN substrate 1 described above.

An exhaust pipe 36 is connected to the process chamber 30. The exhaust pipe 36 is connected to an exhaust system, such as a rotary pump. Accordingly, the pressure inside the process chamber 30 is maintained at 1/10 atmospheric pressure to normal pressure (preferably, about ⅕ atmospheric pressure), and the atmosphere inside the process chamber 30 is exhausted constantly.

Meanwhile, a raw material gas supply channel 40 for supplying a raw material gas toward the surface of the wafer 35 held by the susceptor 32 is introduced into the process chamber 30. Connected to the raw material gas supply channel 40 are a nitrogen raw material pipe 41 for supplying ammonia as a nitrogen raw material gas, a gallium raw material pipe 42 for supplying trimethyl gallium (TMG) as a gallium raw material gas, an aluminum raw material pipe 43 for supplying trimethyl aluminum (TMAl) as an aluminum raw material gas, an indium raw material pipe 44 for supplying a trimethyl indium (TMIn) as an indium raw material gas, a magnesium raw material pipe 45 for supplying ethyl cyclopentadienyl magnesium (EtCp₂Mg) as a magnesium raw material gas, and a silicon raw material pipe 46 for supplying silane (SiH₄) as a silicon raw material gas. Valves 51 through 56 are interposed in these raw material pipes 41 through 46, respectively. Each raw material gas is supplied together with a carrier gas made of hydrogen or nitrogen or both.

For example, a GaN single crystalline wafer having the principal plane in m-plane is held by the susceptor 32 as the wafer 35. In this state, a carrier gas and an ammonia gas (nitrogen raw material gas) are supplied inside the process chamber 30 with opening the nitrogen raw material valve 51 while keeping the valves 52 through 56 closed. Further, the heater 31 is energized and the wafer temperature is raised to 1000° C. to 1100° C. (for example, 1050° C.). It is thus possible to grow a GaN semiconductor without causing any roughness on the surface.

After the sequence waits until the wafer temperature reaches 1000° C. to 1100° C., the nitrogen raw material valve 51, the gallium raw material valve 52, and the silicon raw material valve 56 are opened. Accordingly, ammonia, trimethyl gallium, and silane together with a carrier gas are supplied from the raw material gas supply channel 40. Consequently, the n-type contact layer 21 formed of a silicon-doped GaN layer is grown on the surface of the wafer 35.

After the n-type contact layer 21 is formed, the multiple-quantum well layer 22 is grown by closing the silicon raw material valve 56. The multiple-quantum well layer 22 is grown by alternately performing a step of growing an InGaN layer by supplying ammonia, trimethyl gallium, and trimethyl indium to the wafer 35 by opening the nitrogen raw material valve 51, the gallium raw material valve 52, and indium raw material valve 54 and a step of growing an additive-free GaN layer by supplying ammonia and trimethyl gallium to the wafer 35 by closing the indium raw material valve 54 and opening the nitrogen raw material valve 51 and the gallium raw material valve 52. For example, the GaN layer is formed first, and the InGaN layer is formed thereon. After these steps are performed repetitively five times, the GaN final barrier layer 25 is formed on the uppermost InGaN layer. It should be noted, however, that it is necessary to change a flow rate ratio of the indium raw material gas, the gallium raw material gas, and the nitrogen raw material gas while the first quantum well layer 221 is formed and while the second quantum well layer 222 is formed, so that an indium composition depending on the emission wavelength is obtained. While the multiple-quantum well layer 22 and the GaN final barrier layer 25 are formed, it is preferable that the temperature of the wafer 35 is, for example, at 700° C. to 800° C. (for example, 730° C.).

Subsequently, the p-type electron block layer 23 is formed. More specifically, the nitrogen raw material valve 51, the gallium raw material valve 52, the aluminum raw material valve 53, and the magnesium raw material valve 55 are opened, and the other valves 54 and 56 are closed. Accordingly, ammonia, trimethyl gallium, trimethyl aluminum, and ethyl cyclopentadienyl magnesium are supplied toward the wafer 35, and the p-type electron block layer 23 formed of a magnesium-doped AlGaN layer is formed. While the p-type electron block layer 23 is formed, it is preferable that the temperature of the wafer 35 is at 800° C. or higher (for example, 100° C.).

Subsequently, the p-type contact layer 24 is formed. More specifically, the nitrogen raw material 51, the gallium raw material valve 52, and the magnesium raw material valve 55 are opened, and the other valves 53, 54, and 56 are closed. Accordingly, ammonia, trimethyl gallium, and ethyl cyclopentadienyl magnesium are supplied toward the wafer 35, and the p-type contact layer 24 made of a magnesium-doped GaN layer is formed. While the p-type contact layer 24 is formed, it is preferable that the temperature of the wafer 35 is at 800° C. or higher (for example, 1000° C.).

When the group III nitride semiconductor layer 2 is grown on the wafer 35 in this manner, the wafer 35 is moved into an etching device, and as is shown in FIG. 1, the recessed portion 7 to expose the n-type contact layer 21 is formed, for example, by plasma etching. The recessed portion 7 may be formed in an island shape so as to surround the multiple-quantum well layer 22, the p-type electron block layer 23, and the p-type contact layer 24, so that the multiple-quantum well layer 22, the p-type electron block layer 23, and the p-type contact layer 24 are shaped in a mesa form.

Further, the anode electrode 3 and the cathode electrode 5 are formed by a metal depositing device using resistance heating or electron ray beams. It is thus possible to obtain the light emitting diode structure shown in FIG. 1.

After the wafer process as described above, individual elements are cut out by cleaving the wafer 35. Each of the individual elements is bonded to the wires 11 and 12 on the support substrate 10 via the bonding metal layer 17 and the conducting material 18.

As has been descried, according to this embodiment, because the multiple-quantum well layer 22 (active layer) generates light in the wavelength range less than 500 nm (more preferably, less than 400 nm), it stands strong against damage and has high emission efficiency. Additionally, because the GaN substrate 1 that emits light upon receipt of UV light generated in the multiple-quantum well layer 22 emits yellow light from a point defect portion in the inside thereof, it has good chromatic stability. Accordingly, it is possible to achieve a white light emitting element having high emission efficiency. Moreover, there is no need for a tedious work, such as applying a light emitting material after the light emitting diode chip is assembled. A white light emitting element can be thus obtained by merely assembling the light emitting diode chip.

When the principal plane of the GaN substrate 1 lies in m-plane, blue light generated from the multiple-quantum well layer 22 is light polarized significantly in a-axis direction. On the contrary, because yellow light generated from the GaN substrate 1 is light emitted from a point defect portion, it is random polarized light.

FIG. 4 is a schematic view showing an example of a device exploiting that blue polarized light is generated from the multiple-quantum well layer 22 and yellow random polarized light is generated from the GaN substrate 1. This device includes a nitride semiconductor light emitting element 60 of the configuration shown in FIG. 1, a polarization control medium 61, and a polarization filter 62.

The nitride semiconductor light emitting element 60 and the polarization filter 62 are disposed oppositely, and the polarization control medium 61 is disposed in between. The polarization filter 62 transmits a polarization component along the transmitting polarization direction S and attenuates the other polarization components to substantially block. Meanwhile, the blue light generated from the nitride semiconductor light emitting element 60 is polarized in the polarization direction P. The nitride semiconductor light emitting element 60 and the polarization filter 62 are disposed so that the polarization direction P and the transmitting polarization direction S become parallel to each other.

The polarization control medium 61 is a medium that can be controlled in a state where the polarization state of incident light is disturbed and a state where incident light is allowed to pass through without disturbing polarization. An example of the polarization control medium 61 is liquid crystals.

When the polarization control medium 61 is in a state where it does not disturb polarization, the blue polarized light generated from the nitride semiconductor light emitting element 60 passes through the polarization control medium 61 while maintaining the polarization state intact and reaches the polarization filter 62. Hence, it passes through the polarization filter 62 while hardly being attenuated by the polarization filter 62. Meanwhile, when the polarization control medium 61 is in a state where it disturbs polarization, the polarization state of the blue polarized light generated from the nitride semiconductor light emitting element 60 is disturbed by the polarization control medium 61, and reaches the polarization filter 62 in the form of random polarized light. The light is therefore attenuated significantly by the polarization filter 62.

For example, if a light amount ratio of the blue light and yellow light passing through the polarization filter 62 is 1:1 when the polarization control medium 61 is controlled to be in the state where it does not disturb polarization, then white light is observed. When the polarization control medium 61 is controlled to be in the state where it disturbs polarization under the same condition, then the blue light is attenuated significantly, resulting in the light amount ratio of the blue light and yellow light to 0.1:1, for example. Accordingly, substantially the yellow light is observed. By controlling the states of the polarization control medium 61 in this manner, it is possible to change colors of light emission between blue and yellow.

The polarization filter 62 may be polarization spectacles worn by an observer. In this case, the same operation as described above can also be achieved.

When the polarization control medium 61 is controlled to be in the state where it does not disturb polarization, the color of light to be observed changes between two colors depending on whether or not the observer wears the polarization spectacles. However, there is no need to provide the polarization control medium 61 under such usage.

While the embodiments of the invention have been described, the invention can be practiced in still another embodiment. For example, in the embodiment above, the white light is emitted by mixing the blue light and yellow light by generating UV light and blue light from the multiple-quantum well layer 22. However, it maybe configured such that UV light alone is generated from the multiple-quantum well layer 22 and light in the wavelength band from green to yellow is generated from the GaN substrate 1 to extract the colored light.

Additionally, the embodiment above chiefly described an example using the GaN substrate 1 having the principal plane in m-plane. However, a GaN substrate having the principal plane in a-plane may also be used as well. Further, a GaN substrate that uses a semi-polar plane, such as (10-11) plane, (10-13) plane, and (11-22) plane, as the principal plane may be also used.

Further, the embodiment above describes a case where the group III nitride semiconductor is epitaxially grown on the GaN substrate 1 by MOCVD. However, another epitaxial growth method, such as hydride vapor phase epitaxy (HVPE), is also applicable.

While the embodiments of the invention have been described in detail, it should be appreciated that these embodiments merely represent examples to provide clear understanding of the technical contents of the invention, and the invention is not limited to these examples. The sprit and the scope of the invention, therefore, are limited solely by the scope of the appended claims.

This application is based upon Japanese Patent Application No. 2007-77037 filed with the Japanese Patent Office on Mar. 23, 2007, the entire disclosure of which is incorporated herein by reference.

What is claimed is:

1. A light emitting element, comprising:
a group III nitride semiconductor substrate that emits a light by absorbing a UV ray: and
a light emitting diode structure, formed of a group III nitride semiconductor grown on the group III nitride semiconductor substrate, having a p-type layer, an active layer that emits a light having a wavelength in a UV region, and an n-type layer.

2. The light emitting element according to claim 1, wherein the group III nitride semiconductor substrate has a principal plane of a non-polar plane or a semi-polar plane; and
the group III nitride semiconductor having a same plane orientation as that of the principal plane is grown on the principal plane.

3. The light emitting element according to claim 1, wherein the group III nitride semiconductor substrate generates a light having a peak wavelength of 500 nm to 600 nm by absorbing the UV ray; and
the active layer has a multiple-quantum well structure including a first quantum well layer that generates a light having a wavelength in a UV region and a second quantum well layer that generates a visible light having a wavelength less than 500 nm.

4. The light emitting element according to claim 2, wherein the group III nitride semiconductor substrate generates a light having a peak wavelength of 500 nm to 600 nm by absorbing a UV ray; and
the active layer has a multiple-quantum well structure including a first quantum well layer that generates a light having a wavelength in a UV region and a second quantum well layer that generates a visible light having a wavelength less than 500 nm.

5. The light emitting element according to claim 3, wherein the light generated from the group III nitride semiconductor substrate and the light generated from the second quantum well layer have different polarization degrees.

6. The light emitting element according to claim 4, wherein the light generated from the group III nitride semiconductor substrate and the light generated from the second quantum well layer have different polarization degrees.

7. The light emitting element according to claim 3, wherein the light generated from the group III nitride semiconductor substrate is not polarized and the light generated from the second quantum well layer is polarized.

8. The light emitting element according to claim 4, wherein the light generated from the group III nitride semiconductor substrate is not polarized and the light generated from the second quantum well layer is polarized.

9. The light emitting element according to claim 1, wherein the light is extracted from a side of the group III nitride semiconductor substrate.

10. The light emitting element according to claim 2, wherein the light is extracted from a side of the group III nitride semiconductor substrate.

11. The light emitting element according to claim 1, wherein a light extract surface is a mirror surface.

12. The light emitting element according to claim 2, wherein a light extract surface is a mirror surface.

13. The light emitting element according to claim 3, wherein a light extract surface is a mirror surface.

14. The light emitting element according to claim 4, wherein a light extract surface is a mirror surface.

15. The light emitting element according to claim 5, wherein a light extract surface is a mirror surface.

16. The light emitting element according to claim 6, wherein a light extract surface is a mirror surface.

17. The light emitting element according to claim 7, wherein a light extract surface is a mirror surface.

18. The light emitting element according to claim 8, wherein a light extract surface is a mirror surface.

19. The light emitting element according to claim 9, wherein a light extract surface is a mirror surface.

20. The light emitting element according to claim 10, wherein a light extract surface is a mirror surface.
